(19) United States
(12) Patent Application Publication
(10) Pub. No.: US 2021/0135637 A1
(43) Pub. Date: May 6, 2021

(54) AMPLIFIER

(71) Applicant: SUMITOMO ELECTRIC INDUSTRIES, LTD., Osaka (JP)

(72) Inventor: Takeshi KAWASAKI, Osaka (JP)

(73) Assignee: SUMITOMO ELECTRIC INDUSTRIES, LTD., Osaka (JP)

(21) Appl. No.: 16/673,075

(22) Filed: Nov. 4, 2019

(51) Int. Cl. H03F 3/193; H03F 1/02; H03F 3/16; H03F 3/60

(52) U.S. Cl. CPC H03F 3/193; H03F 3/60; H03F 3/16; H03F 1/0283

(57) ABSTRACT

An multistage amplifier includes first to third FETs, a drain of the second FET is connected to a gate of the third FET in an AC manner, a source thereof is grounded in a DC manner, a drain of the first FET is connected to a gate of the second FET in an AC manner, a source thereof is grounded in a DC manner, a gate thereof receives a high frequency signal, a drain of the third FET receives a bias current and outputs an amplified signal, a source thereof is grounded in an AC manner, the drains of the first and second FETs are connected to the source of the third FET in a DC manner via a transmission line having an electrical length of λ/4 when a wavelength of the high frequency signal is λ, and a size of third FET is greater than other FETs.

### TECHNICAL FIELD

One aspect of the present disclosure relates to an amplifier that amplifies an electrical signal.

### BACKGROUND

As a configuration of an amplifier that amplifies an electrical signal at a high frequency, for example, a configuration in which three field effect transistors (FETs) are included as described in Patent Document 1 (Japanese Unexamined Patent Publication No. H7-283657) is known. In this amplifier, a gate bias to be applied to a gate of the FET, which is an active element, is changed according to a magnitude of an envelope of an input signal or an output signal.

An amplifier described in Patent Document 2 (Japanese Unexamined Patent Publication No. 2014-72696) is a multistage amplification circuit including a plurality of FETs and has a configuration in which a common current is supplied from drains to sources of the plurality of FETs. With such a configuration, power consumption can be reduced and a circuit size can be reduced through reduction in size of a power supply circuit.

In the amplifier described in Patent Document 2, providing an FET having a small size (for example, a small gate width) at a front stage and making a size of the FET at a rear stage greater than that of the FET at the front stage are suitable for reduction in power consumption, and linearity of a gain. On the other hand, in a structure of the related art in which a common current is supplied to FETs connected in multiple stages, power efficiency tends to be degraded. In the amplifier described in Patent Document 2, the size of the FET at a first stage is made smaller than that of the FET at a rear stage, a current shunt circuit connected in parallel to the FET at the first stage is provided, and a part of a current flowing out of the FET at the rear stage is shunted, thereby realizing linearity of a gain. However, in such a configuration, a current flowing into the current shunt circuit becomes an idle current and does not contribute to signal amplification. Therefore, it is desired to achieve both reduction in power consumption and linearity of a gain in the amplifier.

### SUMMARY

An amplifier according to an aspect of the present disclosure is a multistage amplifier including N first to N-th transistors (N is an integer equal to or greater than 3) each having first and second current terminals and a control terminal, wherein the first current terminal of the m-th transistor (m is an integer satisfying 1<m<N) is connected to the control terminal of the (m+1)-th transistor in an alternating current manner, and the second current terminal of the m-th transistor is grounded in a direct current manner; the first current terminal of the first transistor is connected to the control terminal of the second transistor in an alternating current manner, the second current terminal of the first transistor is grounded in a direct current manner, and the control terminal of the first transistor is configured to receive a high frequency signal; the first current terminal of the N-th transistor is configured to receive a bias current and output an amplified signal, and the second current terminal of the N-th transistor is grounded in an alternating current manner; and the first current terminal of each of the first to (N−1)-th transistors is connected to the second current terminal of the N-th transistor in a direct current manner via a transmission line having an electrical length of λ/4 when a wavelength of the high frequency signal is λ, a size of the N-th transistor being greater than those of the first to (N−1)-th transistors.

### BRIEF DESCRIPTION OF THE DRAWINGS

FIG. 1 is a circuit diagram of an amplifier according to an embodiment.

FIG. 2 is a diagram illustrating a circuit pattern of the amplifier of FIG. 1.

FIG. 3 is a circuit diagram of the amplifier according to a modification example.

FIG. 4A is a diagram illustrating a configuration of an application example of the embodiment.

FIG. 4B is a diagram illustrating a configuration of an application example of the embodiment.

### DETAILED DESCRIPTION

Hereinafter, an embodiment of the present disclosure will be described with reference to the drawings. In description of the drawings, the same elements are denoted by the same reference numerals, and redundant descriptions will be omitted.

### [Configuration of Amplifier]

FIG. 1 is a circuit diagram of an amplifier according to an embodiment. As illustrated in FIG. 1, an amplifier 1 is a circuit that amplifies a high frequency signal (for example, a high frequency signal in a band of tens of GHz), and has a configuration in which three transistors are connected in multiple stages. That is, the amplifier 1 includes first to third FETs Tr1, Tr2, and Tr3, which are three field effect transistors each having a gate (a control terminal), a drain (a first current terminal), and a source (a second current terminal). In the first to third FETs Tr1, Tr2, and Tr3, sizes of the first and second FETs Tr1 and Tr2 are set to be smaller than a size of the third FET Tr3 at a final stage. Specifically, a sum of gate widths of the first and second FETs Tr1 and Tr2 is set to be substantially equal to a gate width of the third FET Tr3 at the final stage, and the gate widths of the first and second FETs Tr1 and Tr2 are set to be substantially equal to each other. For example, the gate widths of the first and second FETs Tr1 and Tr2 are set to 300 μm, and the gate width of the third FET Tr3 is set to 600 μm.

The gate of the first FET Tr1 is connected to an input terminal I_{N} in an alternating current manner via a transmission line X1 and a capacitor C1, and the source thereof is electrically connected (grounded) to a ground potential via a transmission line Y1. This input terminal I_{N} is a terminal for input of an AC input signal. In addition, the gate of the first FET Tr1 is electrically connected to a power supply terminal VG for gate bias application via a transmission line Z1, and the power supply terminal VG is grounded in an alternating current manner via a capacitor C4.

The gate of the second FET Tr2 is connected to the drain of the first FET Tr1 in an alternating current manner via a transmission line X2 and a capacitor C2, and the source thereof is grounded via a transmission line Y2. In addition, the gate of the second FET Tr2 is connected to the power supply terminal VG for gate bias application via a transmission line L0. In other words, a common (same) gate bias is applied to the gates of the first FET Tr1 and the second FET Tr2.

The gate of the third FET Tr3 is connected to the drain of the second FET Tr2 in an alternating current manner via a transmission line X3 and a capacitor C3, and the source thereof is grounded in an alternating current manner via a transmission line Y3 and a capacitor C7. In addition, the drain of the third FET Tr3 is connected to an output terminal O_{UT} for AC output signal output in an alternating current manner via wires W1 and W2, a transmission line X4, and a capacitor C9, and is connected to a power supply terminal VD for bias voltage application via a transmission line Z4. Further, the gate of the third FET Tr3 is connected to the power supply terminal VD via three resistive elements R1 to R3 and the transmission line Z4. In the third FET Tr3 having such a configuration, when a bias voltage is applied to the power supply terminal VD, a bias current is supplied from the drain to the source, and a bias voltage set by the resistive elements R1 to R3 is applied to the gate.

Further, in the amplifier 1 of the embodiment, the respective drains of the first to second FETs Tr1 and Tr2 are connected to the source of the third FET Tr3 in a direct current manner via shunt circuits SH1 and SH2. These shunt circuits SH1 and SH2 are circuits for shunting a bias current that is supplied between the drain and the source of the third FET Tr3 from the power supply terminal VD, to the first to second FETs Tr1 and Tr2.

The shunt circuit SH1 includes a transmission line Z2 having one end connected to the drain of the first FET Tr1, a transmission line L1 connected between the other end of the transmission line Z2 and the source of the third FET Tr3, and a capacitor C5 via which a connection point between the two transmission lines Z2 and L1 is grounded in an alternating current manner. The transmission line Z2 is set to have an electrical length of a ¼ wavelength (λ/4) to correspond to a frequency of the AC input signal. For example, when the AC input signal is in a 70 GHz band, a characteristic wavelength λ thereof is about 1,600 μm on a semiconductor substrate, and a transmission path length is set to 400 μm in a monolithic microwave integrated circuit (MMIC) in which the circuit of FIG. 1 is realized on a semiconductor substrate. In the shunt circuit SH1 having such a configuration, since the connection point between the two transmission lines Z2 and L1 is grounded in an alternating current manner, and the electrical length of the transmission line Z2 is set to λ/4, the transmission line Z2 is regarded as being open in an alternating current manner when viewed from the drain side of the first FET Tr1, whereas the drain of the first FET Tr1 and the source of the third FET Tr3 are connected in a direct current manner.

Similarly, the shunt circuit SH2 includes a transmission line Z3 having one end connected to the drain of the second FET Tr2, a transmission line L2 connected between the other end of the transmission line Z3 and the source of the third FET Tr3, and a capacitor C6 via which a connection point between the two transmission lines Z3 and L2 is grounded in an alternating current manner. The transmission line Z3 is set to have an electrical length of a ¼ wavelength to correspond to the frequency of the AC input signal, similar to the transmission line Z2. In the shunt circuit SH2 having such a configuration, the transmission line Z3 is regarded as being open in an alternating current manner when viewed from the drain side of the second FET Tr2, whereas the drain of the second FET Tr2 and the source of the third FET Tr3 are connected in a direct current manner.

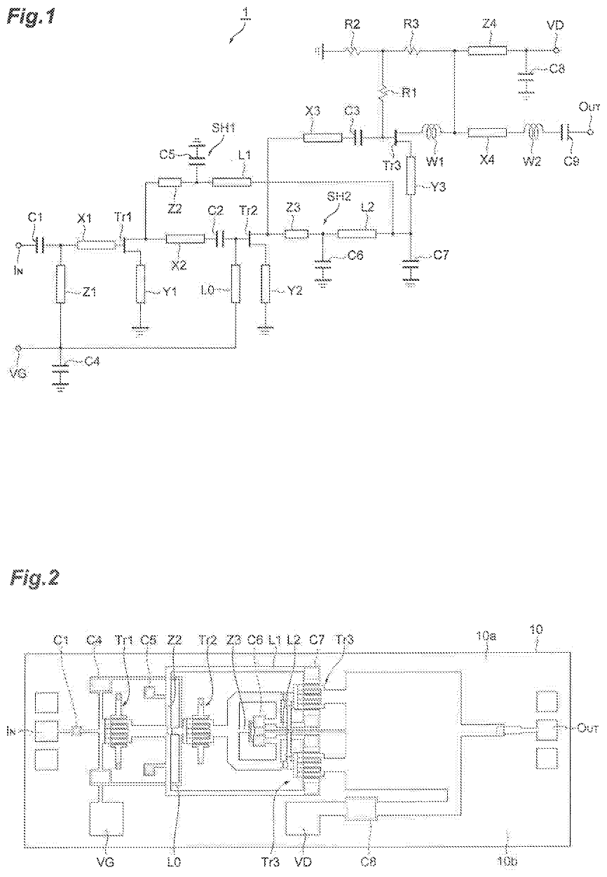

FIG. 2 is a diagram illustrating a circuit formation pattern of the amplifier 1. Thus, each element constituting the amplifier 1 is formed on a front surface 10a of a semiconductor chip 10 constituted by a GaAs substrate or the like, and a back surface 10b of the semiconductor chip 10 is set to a ground potential. The respective capacitors C1, C4, C5, C6, C7, and C8 are formed as metal-insulator-metal (MIM) structures in the semiconductor chip 10, and the respective transmission lines Z2, Z3, L0, L1, and L2 are formed as linear metal patterns on the semiconductor chip 10.

An operation of the amplifier 1 according to the embodiment will be described.

In the amplifier 1 having the above configuration, it is assumed that a common gate bias is applied to the first and second FETs Tr1 and Tr2, and a different gate bias is applied to the third FET Tr3. As an example, it is assumed that a common gate bias is used for the two gate biases, that is, the common gate bias is applied to the first to third FETs Tr1 to Tr3. In this case, a ratio between a current flowing between the drain and the source of the FET Tr3 and a sum of currents flowing between the drain and the source of the respective FETs Tr1 and Tr2 is set to a value corresponding to a ratio between the gate widths. Therefore, even when it is assumed that all the FETs are driven under the same bias conditions, the amplifier is very advantageous in terms of improvement of power efficiency and reduction in distortion, as compared with a multistage amplification circuit of the related art.

The AC input signal (a high frequency signal) input to the input terminal I_{N} is first applied to the gate of the first FET Tr1 and amplified by the first FET Tr1. Thereafter, the high frequency signal is applied to the gate of the second FET Tr2 via the capacitor C2 and further amplified by the second FET Tr2. In this case, the gate bias is applied to the gates of the two FETs Tr1 and Tr2 via the transmission lines Z1 and L0 having a length of a ¼ wavelength to correspond to a wavelength of the AC input signal. Since this gate bias is grounded in an alternating current manner via the capacitor C4, output ends of the transmission lines Z1 and L0 (the sides on which an AC signal flows) are regarded as being open in an alternating current manner, and transmission of the AC input signal is not influenced. A transmission line is also connected between the output ends of the transmission lines Z1 and L0 and the gates of the FETs Tr1 and 2, but transmission of the high frequency signal is not influenced since a length of the transmission line is shorter than the wavelength of the high frequency signal.

The drain of the second FET Tr2 is connected to the source of the third transistor Tr3 in a direct current manner via the shunt circuit SH2, and is connected to the gate of the third transistor Tr3 in an alternating current manner via the capacitor C3. Further, the drain of the first FET Tr1 is connected to the source of the third transistor Tr3 in a direct current manner via the shunt circuit SH1. Accordingly, the high frequency signal is amplified by the third FET Tr3 and output as a high frequency output signal. At the same time, the bias current is supplied from the source of the third FET Tr3 to the drains of the FETs Tr1 and Tr2 via the transmission lines Z2 and Z3 having a length of a ¼ wavelength.

With the amplifier 1 described above, since the gate width of the FET Tr3 at the final stage is set to be substantially equal to a sum of the gate widths of the FETs other than the FET at the final stage, it is possible to achieve an increase in gain and high efficiency. Further, the configuration of the embodiment can be applied not only to a power amplifier, but also to an amplifier other than a power amplifier or an amplifier for amplification of a signal in various frequency bands.

That is, in the amplifier 1, the AC input signal is amplified in the three FETs constituting a multistage amplification circuit. In this case, the bias current from the power supply terminal VD that is supplied from the drain to the source of the third FET Tr3 branches and is supplied to the drains of the first and second FETs Tr1 and Tr2. With this configuration, the bias current supplied from the power supply terminal VD can be efficiently used, and the bias current supplied to the first and second FETs Tr1 and Tr2 can be set to be smaller than the bias current supplied to the third FET Tr3 at the final stage. In addition, the size of the third FET Tr3 at the final stage is set to be greater than the sizes of the first and second FETs Tr1 and Tr2. As a result, it is possible to achieve reduction in power consumption and to realize linearity of a gain in the entire multistage amplification circuit.

In particular, a sum of the sizes of the first and second FETs Tr1 and Tr2 is substantially equal to the size of the third FET Tr3. With such a configuration, it is possible to make the sizes of the first and second FETs Tr1 and Tr2 smaller than that of the third FET Tr3 at the final stage, to sequentially increase the current flowing through the drain and the source even when the same gate bias is applied to all the FETs, and to realize linearity of the gain in the entire multistage amplification circuit.

Further, the drain of the first FET Tr1 is connected to the source of the third FET Tr3 via the transmission line Z2 having an electrical length of λ/4 and to the gate of the second FET Tr2 via the other transmission line X2. The drain of the second FET Tr2 is connected to the source of the third FET Tr3 via the transmission line Z3 having an electrical length of λ/4 and to the gate of the third FET Tr3 via the other transmission line X3. With such a configuration, it is possible to sequentially appropriately amplify the input high frequency signal and propagate the high frequency signal to the FET Tr3 at the final stage, and to increase a gain of the amplifier.

Further, the gate bias can be applied to the third FET Tr3 independently of the other FETs. With such a configuration, it is possible to individually control an operating point of the third FET Tr3 and to realize linearity of a gain more reliably.

Although principles of the present disclosure have been illustrated and described in the preferred embodiment, it will be appreciated by those skilled in the art that the present disclosure can be modified in disposition and details without departing from such principles. The present disclosure is not limited to a specific configuration disclosed in the embodiment. Therefore, rights for all corrections and changes within the claims and the spirit thereof are claimed.

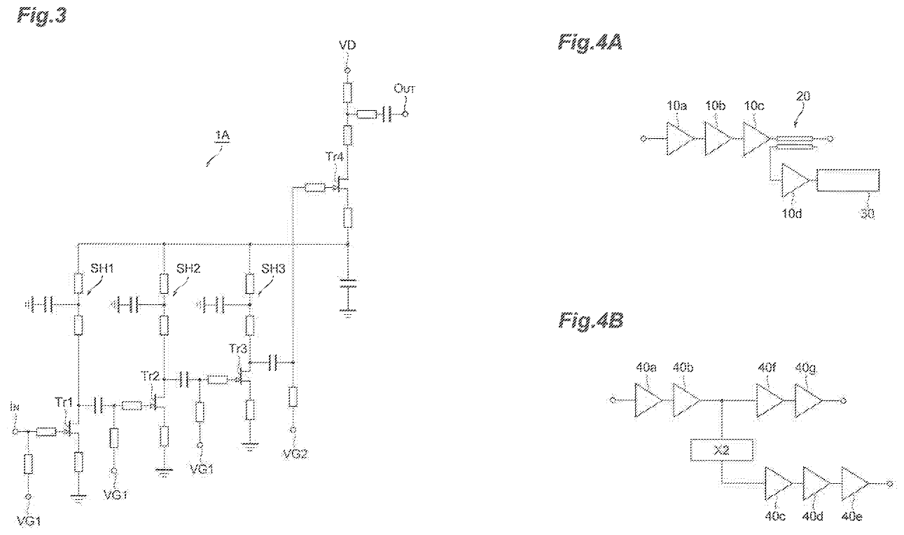

For example, the number of transistor stages constituting the amplifier in the embodiment can be variously changed. FIG. 3 illustrates a configuration of a modification example in which the number of transistor stages has been changed to four. An amplifier 1A illustrated in FIG. 3 includes first to fourth FETs Tr1 to Tr4. For example, a size (a gate width) of the fourth FET Tr4 at a final stage is set to 400 μm, sizes of the first and second FETs Tr1 and Tr2 are set to 100 μm, and a size of the third FET Tr3 is set to 200 μm. A gate bias is applied to the first to third FETs Tr1 to Tr3 using power supply terminals VG1 and another gate bias is applied to the forth FET Tr4 using a power supply terminal VG2. The amplifier 1A equalizes the gate-source voltage of the forth FET Tr4 to the gate bias applied through the power supply terminals VG1, when the another gate bias is set to be larger than the gate bias. Further, drains of the FETs at the front stage are sequentially connected to gates of the FETs at the rear stage in an alternating current manner, and the respective drains of the first to third FETs Tr1 to Tr3 are connected to a source of the fourth FET Tr4 in a direct current manner through shunt circuits SH1 to SH3.

In such a configuration of the modification example, a bias current supplied from the power supply terminal VD to the drain of the fourth FET Tr4 branches and is supplied to the drains of the first to third FETs Tr1 to Tr3. As a result, it is possible to achieve reduction in power consumption and to realize linearity of a gain in an entire multistage amplification circuit.

Here, in the above modification example, it is assumed that the same gate bias is applied to the first to third FETs Tr1 to Tr3. On the other hand, in an actual circuit, the bias current may vary due to the accuracy of manufacturing processes or variation therein even when the same gate bias is applied. Under such a situation, a branching state of a drain current is not as designed, and in extreme cases, the branching state may fluctuate and each FET may oscillate. In particular, in a multistage amplification circuit, it is easy for the stability of a circuit operation to be impaired. In such a case, separate bias voltages may be applied to the gates of transistors other than the transistor at the final stage. Accordingly, it is possible to maintain the stability of an operation of the multistage amplification circuit. In particular, it is particularly effective for the stability of the gate bias applied to the transistor at the final stage. The gate-source voltage of the transistor at the final stage (for example, the FET Tr4) is self-biased to be equal to the gate bias of the other transistors (for example, the FETs Tr1, Tr2 and Tr3) so that the bias current of the transistor at the final stage becomes equal to a sum of the bias currents of the other transistors.

FIGS. 4A and 4B illustrate an application example of the embodiment.

FIG. 4A illustrates an example of a multistage amplification circuit including four transistors. Specifically, this multistage amplification circuit includes three amplifiers 10a, 10b, and 10c including respective transistors of which a size ratio has been set to 1:2:4, a preamplifier 10d that is connected to an output of the amplifier 10c via a coupler 20 and includes a transistor having the same size as that of the amplifier 10a, and a detector 30 that is connected to an output of the preamplifier 10d and detects a power of an amplified signal. For example, the sizes of the transistors constituting the amplifiers 10a and 10d are set to 100 μm, the size of the transistor constituting the amplifier 10b is set to 200 μm, and the size of the transistor constituting the amplifier 10c is set to 400 μm. In such a configuration, a bias current supplied to the amplifier 10c branches to the amplifiers 10a, 10b, and 10d according to the sizes of the transistors thereof.

FIG. 4B illustrates an example in which the embodiment is applied to a multiplication circuit. Specifically, in this multiplication circuit, a high frequency signal at a predetermined frequency (for example, a 38 GHz band) is amplified by two preamplifiers 40a and 40b including respective transistors of which a size ratio has been set to 2:3, and multiplied waves and a fundamental wave are further amplified by a multiplication circuit part and a fundamental circuit part, which branch from the preamplifier. The multiplication circuit part includes three-stage amplifiers 40c, 40d, and 40e of which a size ratio has been set to 1:2:4, and amplifies the multiplied waves (for example, a 76 GHz band). The fundamental circuit part includes two-stage amplifiers 40f and 40g of which a size ratio has been set to 4:8, and amplifies the fundamental wave (for example, a 38 GHz band). For example, the sizes of the transistors constituting the amplifiers 40a and 40d are set to 200 μm, the size of the transistor constituting the amplifier 40b is set to 300 μm, the sizes of the transistors constituting the amplifiers 40f and 40e are set to 400 μm, the size of the transistor constituting the amplifier 40c is set to 100 μm, and the size of the transistor constituting the amplifier 40g is set to 800 μm. In such a configuration, a total bias current supplied to the amplifiers 40g and 40e at final stages in the respective circuit parts can branch to and be shared by the amplifiers 40a, 40b, 40c, 40d, and 40f.

In this example, a configuration in which currents flowing through the transistors at the two final stages are temporarily integrated and then branch to the five other transistors is necessary. In order to eliminate a need for such a configuration, a size ratio of the transistors of the fundamental circuit part may be set to 1:3:4:8, and a size ratio of the transistors of the multiplication circuit part may be set to 1:3:4.

What is claimed is:

1. A multistage amplifier including N first to N-th transistors (N is an integer equal to or greater than 3) each having first and second current terminals and a control terminal,
wherein the first current terminal of the m-th transistor (m is an integer satisfying 1<m<N) is connected to the control terminal of the (m+1)-th transistor in an alternating current manner, and the second current terminal of the m-th transistor is grounded in a direct current manner,
the first current terminal of the first transistor is connected to the control terminal of the second transistor in an alternating current manner, the second current terminal of the first transistor is grounded in a direct current manner, and the control terminal of the first transistor is configured to receive a high frequency signal,
the first current terminal of the N-th transistor is configured to receive a bias current and output an amplified signal, and the second current terminal of the N-th transistor is grounded in an alternating current manner, and
the first current terminal of each of the first to (N−1)-th transistors is connected to the second current terminal of the N-th transistor in a direct current manner via a transmission line having an electrical length of λ/4 when a wavelength of the high frequency signal is λ, a size of the N-th transistor being greater than those of the first to (N−1)-th transistors.

2. The amplifier according to claim 1, wherein a terminal on the second current terminal side of the N-th transistor of the transmission line is grounded via a capacitor.

3. The amplifier according to claim 1, wherein a sum of the sizes of the first to (N−1)-th transistors is equal to the size of the N-th transistor.

4. The amplifier according to claim 1, wherein a bias voltage different from that of the control terminals of the first to (N−1) th transistors is applied to the control terminal of the N-th transistor.

5. The amplifier according to claim 4, wherein different bias voltages are applied to the respective control terminals of the first to (N−1)-th transistors.

6. The amplifier according to claim 1,
wherein the first to N-th transistors are FETs, and
the first current terminal is a drain, the second current terminal is a source, and the control terminal is a gate.
